(19) United States
(12) Patent Application Publication
(10) Pub. No.: US 2009/0045848 A1
(43) Pub. Date: Feb. 19, 2009

(54) PHASE-FREQUENCY DETECTOR WITH HIGH JITTER TOLERANCE

(75) Inventors: Ali Kiaei, Cupertino, CA (US); Gerard G. Socci, Palo Alto, CA (US); Ali Djabbari, Saratoga, CA (US); Ahmad Bahai, Lafayette, CA (US)

Correspondence Address: NATIONAL SEMICONDUCTOR CORPORATION;c/o VEDDER PRICE KAUFMAN & KAMMHOLZ, 222 N. LASALLE STREET, SUITE 2400, CHICAGO, IL, 60601, US

(73) Assignee: National Semiconductor Corporation, Santa Clara, CA (US)

(21) Appl. No.: 11/839,018

(22) Filed: Aug. 15, 2007

(51) Int. Cl. H03D 13/00; G01R 29/00

(52) U.S. Cl. 327/10

(57) ABSTRACT

A phase-frequency detection system and method for enhancing performance of the frequency detector in a phase-frequency detection system. Filtering of the frequency detector inputs makes operation of the frequency detector more robust in the presence of intersymbol interference within the incoming data signal and other non-ideal characteristics such as noise and crosstalk.

### BACKGROUND

1. Field of the Invention

The present invention relates to data clock recovery circuits, and in particular, to phase-frequency detectors for use in detecting a clock signal associated with an incoming data signal.

2. Related Art

Data signals transmitted over a high speed data link, such as a backplane or cable, are often processed by receiver circuits in which a clock signal must be recovered from the binary signal. Such data signals are often transmitted using the well known non-return-to-zero (NRZ) signal format.

Referring to FIG. 1, the clock recovery circuit often used is a phase-locked loop (PLL) 10, implemented substantially as shown. The incoming data signal 11 is processed by a phase-frequency detector 12 which is clocked in accordance with multiple clock signals 21 (discussed in more detail below) to recover and provide the data signal 13d, along with the associated clock signal 21c. The phase-frequency detector 12 also provides a detection signal 13f related to the phase and frequency difference between the incoming data signal and the locally generated clock signal 13c. This signal 13 (which is a combination, e.g., a linear sum, of the respective output signals of the phase detector and frequency detector that together form the phase-frequency detector 12) typically drives a charge pump circuit 14 which provides a voltage signal 15 which, in turn, is filtered by a low pass filter 16. The resulting filtered signal 17 provides a control voltage for a voltage controlled oscillator (VCO) 18, the output signal 19 of which is processed by a clock generator 20 to produce the clock signals 21 for the phase-frequency detector 12. Depending upon the actual implementation of the phase-frequency detector 12, many forms of which are well known in the art, the clock signals 21 will include two quadrature clock signals (i.e., having a mutual phase difference of 90 degrees), or alternatively, four clock signals, two of which have mutually quadrature phases, and two more of which also have mutually quadrature phases. (For example, one pair of clock signals will include a clock signal having a zero degree phase and another clock signal having a 90 degree phase, while the other pair of clock signals will include a clock signal having a phase of 45 degrees and another clock signal having a phase of 135 degrees.)

### SUMMARY

In accordance with the presently claimed invention, a phase-frequency detection system and method are provided for enhancing performance of the frequency detector in a phase-frequency detection system. Filtering of the frequency detector inputs makes operation of the frequency detector more robust in the presence of intersymbol interference within the incoming data signal and other non-ideal characteristics such as noise and crosstalk.

In accordance with one embodiment of the presently claimed invention, a phase-frequency detector for use in detecting a clock signal associated with an incoming data signal includes:

a data electrode to convey a binary data signal having a clock signal associated therewith;

a plurality of clock electrodes to convey a plurality of clock signals having a like plurality of mutually dissimilar clock signal phases;

phase detection circuitry coupled to the data electrode and the plurality of clock electrodes, and responsive to the binary data signal and the plurality of clock signals by providing first and second beat signals corresponding to first and second samples of one or more of the binary data signal and plurality of clock signals;

filter circuitry coupled to the phase detection circuitry and responsive to the first and second beat signals by providing corresponding first and second filtered signals; and

frequency detection circuitry coupled to the filter circuitry and responsive to the first and second filtered signals by providing a detection signal having a value indicative of a frequency difference between the binary data signal and at least one of the plurality of clock signals.

In accordance with another embodiment of the presently claimed invention, a phase-frequency detector for use in detecting a clock signal associated with an incoming data signal includes:

phase detector means for detecting a binary data signal having a clock signal associated therewith and a plurality of clock signals having a like plurality of mutually dissimilar clock signal phases to provide first and second beat signals corresponding to first and second samples of one or more of the binary data signal and plurality of clock signals;

filter means for filtering the first and second beat signals to provide corresponding first and second filtered signals; and

frequency detector means for detecting the first and second filtered signals to provide a detection signal having a value indicative of a frequency difference between the binary data signal and at least one of the plurality of clock signals.

In accordance with still another embodiment of the presently claimed invention, a method of phase-frequency detection for use in detecting a clock signal associated with an incoming data signal includes:

detecting a binary data signal having a clock signal associated therewith and a plurality of clock signals having a like plurality of mutually dissimilar clock signal phases to provide first and second beat signals corresponding to first and second samples of one or more of the binary data signal and plurality of clock signals;

filtering the first and second beat signals to provide corresponding first and second filtered signals; and

detecting the first and second filtered signals to provide a detection signal having a value indicative of a frequency difference between the binary data signal and at least one of the plurality of clock signals.

### BRIEF DESCRIPTION OF THE DRAWINGS

FIG. 1 is a function block diagram of a conventional PLL for recovering data and clock signals.

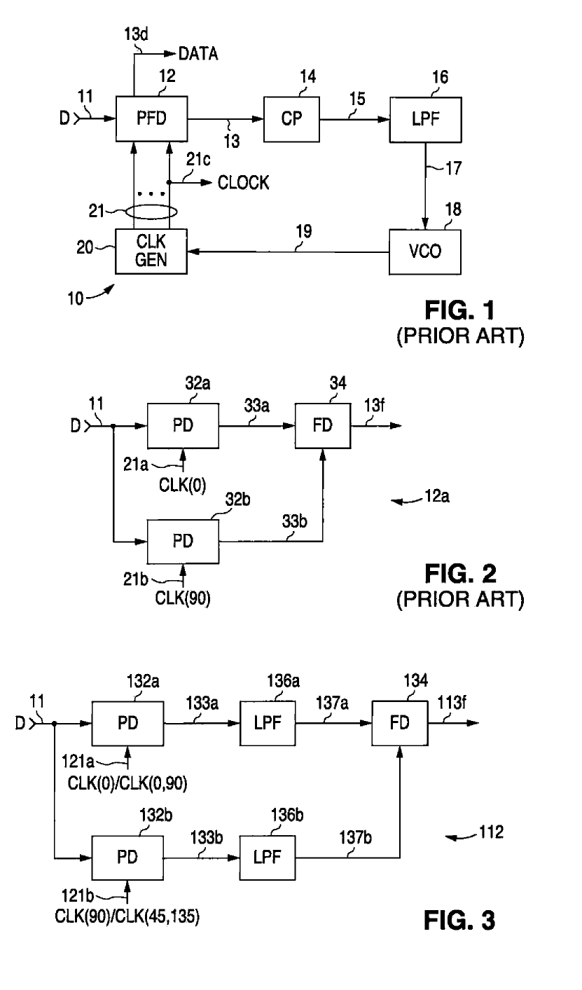

FIG. 2, is a functional block diagram of a conventional phase-frequency detector.

FIG. 3 is a functional block diagram of a phase-frequency detector in accordance with a preferred embodiment of the presently claimed invention.

### DETAILED DESCRIPTION

The following detailed description is of example embodiments of the presently claimed invention with references to the accompanying drawings. Such description is intended to be illustrative and not limiting with respect to the scope of the present invention. Such embodiments are described in sufficient detail to enable one of ordinary skill in the art to practice the subject invention, and it will be understood that other embodiments may be practiced with some variations without departing from the spirit or scope of the subject invention.

Throughout the present disclosure, absent a clear indication to the contrary from the context, it will be understood that individual circuit elements as described may be singular or plural in number. For example, the terms “circuit” and “circuitry” may include either a single component or a plurality of components, which are either active and/or passive and are connected or otherwise coupled together (e.g., as one or more integrated circuit chips) to provide the described function. Additionally, the term “signal” may refer to one or more currents, one or more voltages, or a data signal. Within the drawings, like or related elements will have like or related alpha, numeric or alphanumeric designators. Further, while the present invention has been discussed in the context of implementations using discrete electronic circuitry (preferably in the form of one or more integrated circuit chips), the functions of any part of such circuitry may alternatively be implemented using one or more appropriately programmed processors, depending upon the signal frequencies or data rates to be processed.

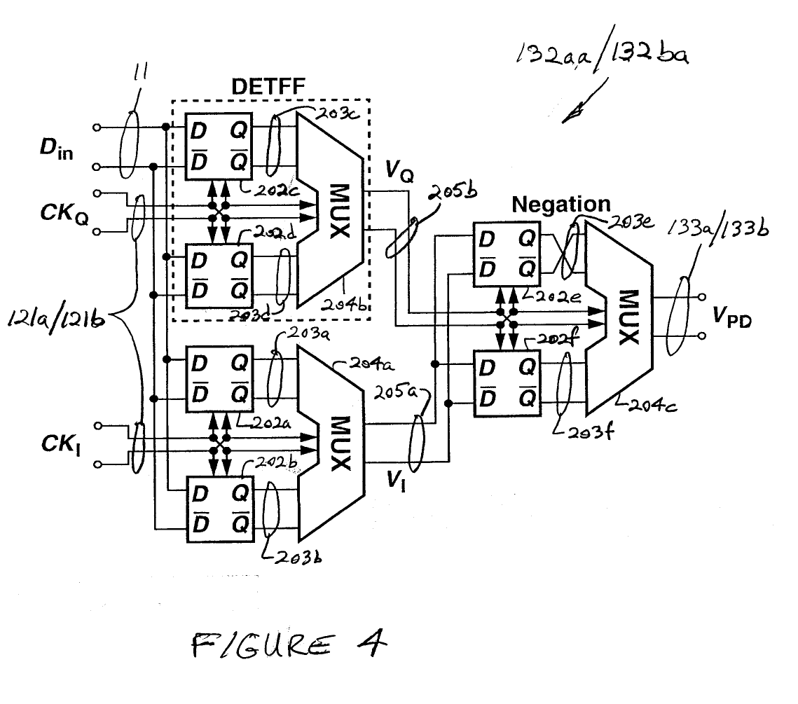

Referring to FIG. 2, one example of a conventional phase-frequency detector 12a includes two binary phase detectors 32a, 32b and a frequency detector 34, interconnected substantially as shown. The phase detectors 32a, 32b are driven by the incoming data signal 11 and clock signals 21a, 21b. The phase detector outputs 33a, 33b contain binary data indicating the phase of the clock signals with respect to the data signal (i.e., earlier or later in phase in the case of binary phase detectors). In some designs, the data signal 11 is sampled by the clock signals 21a, 21b, while in other designs, the clock signals 21a, 21b are sampled by the data signal 11. The resulting phase detection signals 33a, 33b, which are indicative of phase differences between the incoming data signal 11 and the respective clock signals 21a, 21b, are further detected by the frequency detector 34 which provides the frequency detection signal 13f indicative of the frequency difference between the data and clock signals.

The phase detection signals 33a, 33b are beat signals. These beat signals 33a, 33b have frequencies equal to the frequency differences between the incoming data signal 11 and respective clock signals 21a, 21b. However, as a practical matter, these signals 33a, 33b are not ideal beat signals due to jitter induced by intersymbol interference within the input data signal or non-ideal circuit operations due to inherent non-ideal characteristics of the circuit devices within the phase detector circuits 32a, 32b. This jitter causes the outputs 33a, 33b of the phase detectors 32a, 32b to have “glitches” as a result of erroneous phase detection. For example, as the edge of the data signal approaches the edge of the clock signal in a binary phase detector, the phase detector output signal transitions between states (i.e., early and late states). However, because of the jittery nature of the edge of the data signal (due to noise and channel intersymbol interference), the phase detector signal includes glitches, e.g., although the average edge of the signal may be late, the data jitter causes the phase detector to detect the data as being early. This, in turn, causes erroneous frequency detection by the frequency detector 34 which needs to use both beat signals 33a, 33b to determine the polarity of the frequency difference between the incoming data signal 11 and clock signals 21a, 21b.

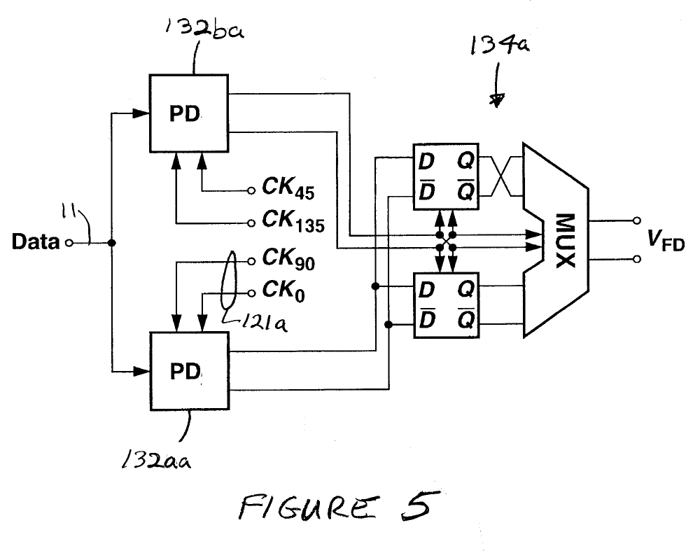

Referring to FIG. 3, a phase-frequency detector 112 in accordance with one embodiment of the presently claimed invention includes two-phase detectors 132a, 132b, two low pass filter circuits 136a, 136b, and a frequency detector 134, interconnected substantially as shown. The phase detectors 132a, 132b and frequency detector 134 operate in accordance with well known principles, as discussed above, to produce phase detection signals 133a, 133b. The low pass filters 136a, 136b filter out, or significantly reduce, high frequency signal transients, or glitches, in the phase detection signals 133a, 133b. The filtered signals 137a, 137b are processed by the frequency detector 134, as discussed above. Accordingly, the frequency detector 134 is now provided with substantially ideal beat signals 137a, 137b, thereby producing a more stable and accurate frequency detection signal 113f. In other words, the filtered beat signals 137a, 137b more accurately represent the average edges of the incoming data signal 11, thereby producing a more robust frequency detection signal 113f. Such filters 136a, 136b can be implemented in analog or digital form, and as linear or nonlinear filters, in accordance with well known principles.

One form of nonlinear filtering that can be used is often referred to as “majority vote” in which the outputs 133a, 133b of the phase detectors 132a, 132b are stored in memories which retain data about a selected number of prior phase detections (i.e., early or late detections). For example, if the stored data indicates that four of the previous five phase detections were late, then the phase detector output will be late too. In other words, the linear lowpass filters 136a, 136b could be replaced by circuitry performing a moving “majority vote” operation. It will be understood that a combination of linear and nonlinear (e.g., “majority vote”) filtering operations could be used to remove the glitches from the phase detector signals.

Various other modifications and alternations in the structure and method of operation of this invention will be apparent to those skilled in the art without departing from the scope and the spirit of the invention. Although the invention has been described in connection with specific preferred embodiments, it should be understood that the invention as claimed should not be unduly limited to such specific embodiments. It is intended that the following claims define the scope of the present invention and that structures and methods within the scope of these claims and their equivalents be covered thereby.

What is claimed is:

1. An apparatus including a phase-frequency detector for use in detecting a clock signal associated with an incoming data signal, comprising:
a data electrode to convey a binary data signal having a clock signal associated therewith;
a plurality of clock electrodes to convey a plurality of clock signals having a like plurality of mutually dissimilar clock signal phases;
phase detection circuitry coupled to said data electrode and said plurality of clock electrodes, and responsive to said binary data signal and said plurality of clock signals by providing first and second beat signals corresponding to first and second samples of one or more of said binary data signal and plurality of clock signals;
filter circuitry coupled to said phase detection circuitry and responsive to said first and second beat signals by providing corresponding first and second filtered signals; and
frequency detection circuitry coupled to said filter circuitry and responsive to said first and second filtered signals by providing a detection signal having a value indicative of a frequency difference between said binary data signal and at least one of said plurality of clock signals.

2. The apparatus of claim 1, wherein said plurality of clock electrodes comprises first and second clock electrodes, and said plurality of mutually dissimilar clock signal phases comprises first and second mutually quadrature signal phases.

3. The apparatus of claim 1, wherein:
said plurality of clock electrodes comprises first, second, third and fourth clock electrodes; and
said plurality of mutually dissimilar clock signal phases comprises first and second mutually quadrature signal phases, and third and fourth mutually quadrature signal phases.

4. The apparatus of claim 1, wherein said phase detection circuitry is responsive to said binary data signal and said plurality of clock signals by providing first and second beat signals corresponding to first and second samples of said binary data signal.

5. The apparatus of claim 1, wherein said phase detection circuitry comprises a plurality of half-rate phase detector circuits.

6. The apparatus of claim 1, wherein said phase detection circuitry comprises:
a first phase detector circuit responsive to said binary data signal and a first portion of said plurality of clock signals by providing said first beat signal; and
a second phase detector circuit responsive to said binary data signal and a second portion of said plurality of clock signals by providing said second beat signal.

7. The apparatus of claim 1, wherein said filter circuitry comprises:
a first low pass filter circuit responsive to said first beat signal by providing a first low pass filtered signal; and
a second low pass filter circuit responsive to said second beat signal by providing a second low pass filtered signal.

8. The apparatus of claim 1, wherein said filter circuitry performs first and second nonlinear majority vote operations.

9. The apparatus of claim 1, wherein said frequency detection circuitry comprises a half-rate frequency detector circuit.

10. The apparatus of claim 1, wherein said frequency detection circuitry is responsive to said first and second filtered signals by providing a ternary signal as said detection signal.

11. An apparatus including a phase-frequency detector for use in detecting a clock signal associated with an incoming data signal, comprising:
phase detector means for detecting a binary data signal having a clock signal associated therewith and a plurality of clock signals having a like plurality of mutually dissimilar clock signal phases to provide first and second beat signals corresponding to first and second samples of one or more of said binary data signal and plurality of clock signals;
filter means for filtering said first and second beat signals to provide corresponding first and second filtered signals; and
frequency detector means for detecting said first and second filtered signals to provide a detection signal having a value indicative of a frequency difference between said binary data signal and at least one of said plurality of clock signals.

12. A method of phase-frequency detection for use in detecting a clock signal associated with an incoming data signal, comprising:
detecting a binary data signal having a clock signal associated therewith and a plurality of clock signals having a like plurality of mutually dissimilar clock signal phases to provide first and second beat signals corresponding to first and second samples of one or more of said binary data signal and plurality of clock signals;
filtering said first and second beat signals to provide corresponding first and second filtered signals; and
detecting said first and second filtered signals to provide a detection signal having a value indicative of a frequency difference between said binary data signal and at least one of said plurality of clock signals.

13. The method of claim 12, wherein said detecting a binary data signal and a plurality of clock signals to provide first and second beat signals comprises detecting said binary data signal and first and second clock signals, wherein said first and second clock signals have first and second mutually quadrature signal phases.

14. The method of claim 12, wherein said detecting a binary data signal and a plurality of clock signals to provide first and second beat signals comprises detecting said binary data signal and first, second, third and fourth clock signals, wherein said first, second, third and fourth clock signals have first and second mutually quadrature signal phases, and third and fourth mutually quadrature signal phases.

15. The method of claim 12, wherein said detecting a binary data signal and a plurality of clock signals to provide first and second beat signals comprises detecting said binary data signal and plurality of clock signals to provide first and second beat signals corresponding to first and second samples of said binary data signal.

16. The method of claim 12, wherein said detecting a binary data signal and a plurality of clock signals to provide first and second beat signals comprises detecting said binary data signal and plurality of clock signals via half-rate phase detection.

17. The method of claim 12, wherein said detecting a binary data signal and a plurality of clock signals to provide first and second beat signals comprises:
detecting said binary data signal and a first portion of said plurality of clock signals to provide said first beat signal; and
detecting said binary data signal and a second portion of said plurality of clock signals to provide said second beat signal.

18. The method of claim 12, wherein said filtering said first and second beat signals to provide corresponding first and second filtered signals comprises:
filtering said first beat signal to provide a first low pass filtered signal; and
filtering said second beat signal to provide a second low pass filtered signal.

19. The method of claim 12, wherein said detecting said first and second filtered signals to provide a detection signal comprises detecting said first and second filtered signals via half-rate frequency detection.

20. The method of claim 12, wherein said detecting said first and second filtered signals to provide a detection signal comprises detecting said first and second filtered signals to provide a ternary signal as said detection signal.
